(19) United States
(12) Patent Application Publication
(10) Pub. No.: US 2025/0250677 A1
(43) Pub. Date: Aug. 7, 2025

(54) ACHIEVING WAFER BACKSIDE PRESSURE BY SHARED GAS CONTROLLER

(71) Applicant: Applied Materials, Inc., Santa Clara, CA (US)

(72) Inventors: Thomas BREZOCZKY, Los Gatos, CA (US); Lakshmikanth Krishnamurthy SHIRAHATTI, Bangalore (IN); Prashant A. DESAI, Bangalore (IN); Kirankumar SAVANDAIAH, Bangalore (IN)

(21) Appl. No.: 18/433,993

(22) Filed: Feb. 6, 2024

(51) Int. Cl. C23C 16/52; C23C 16/455

(52) U.S. Cl. CPC C23C 16/52; C23C 16/45561; C23C 16/45597

(57) ABSTRACT

Embodiments described herein generally pertain to a system and method for resource sharing among processing stations in a substrate processing system. The system including at least a first processing chamber with a first processing volume, a substrate support disposed within the first processing volume having a first backside gas delivery port, a backside gas conduit, a gas delivery port, a first inlet valve between a central junction and an inlet junction, and a first bypass valve between the central junction and a first bypass port. The system includes a pressure controller with an inlet and outlet; the outlet connects to the inlet junction. Also, a flow-regulating orifice with an inlet coupled to a gas source and an outlet communicating with the pressure controller's inlet.

### BACKGROUND

### Field

Embodiments of the present invention generally relate to a method of sharing gas resources among the various stations of a substrate processing system.

### Description of the Related Art

The fabrication of semiconductor structures and devices rely on a multitude of resources and subsystems, such as a gas delivery system, to provide required resources to the various processing stations of a substrate processing system.

The gas delivery systems play a critical role in semiconductor manufacturing processes. They are responsible for delivering precise quantities and purity of various gases to enable the fabrication of semiconductor devices with high accuracy, reliability, and safety. These complex systems ensure that the necessary gases are delivered in a controlled manner to meet the stringent requirements of semiconductor fabrication processes.

Gas delivery systems in semiconductor manufacturing typically involve complex systems which in gas sources, delivery lines, delivery control modules, purification systems, distribution systems, and monitoring systems. The various systems, modules, and components that form a gas delivery system are both complex and expensive. One such example system is the backside gas delivery system. In physical vapor deposition (PVD) applications, backside gas is delivered to the underside of a clamped substrate to provide for convective heat transfer between the substrate, and the electrostatic chuck. Current backside gas delivery systems are slow, not shareable between processing stations, imprecise, require expensive mass flow controllers, and require manual calibration and service to maintain performance. Accordingly, there is a need in the art for a more efficient implementation and utilization of gas resources.

### SUMMARY

Embodiments described herein generally relate to resource sharing among the various processing stations of a substrate processing system. More particularly, embodiments described herein provide methods for more efficient, and less complicated, utilization of gas resources.

In one embodiment, a substrate processing system is provided. The substrate processing system includes a first processing chamber having one or more walls defining a first processing volume, a first substrate support disposed in the first processing volume, where the first substrate support having a first backside gas delivery port, a first backside gas conduit having a first end that is in fluid communication with the first backside gas delivery port and a second end that is in fluid communication with a central junction, a first inlet valve disposed between the central junction and an inlet junction, and a first bypass valve disposed between the central junction and a first bypass port, where the first bypass port is in fluid communication with the first processing volume. The substrate processing system includes a second processing chamber having one or more walls defining a second processing volume, a second substrate support disposed in the second processing volume, where the second substrate support having a second backside gas delivery port, a second backside gas conduit having a first end that is in fluid communication with the second backside gas delivery port and a second end that is in fluid communication with a central junction, a second inlet valve disposed between the central junction and the inlet junction, and a second bypass valve disposed between the central junction and a second bypass port, where the second bypass port is in fluid communication with the second processing volume. The substrate processing system includes a pressure controller having an inlet and an outlet, where the outlet of the pressure controller is in fluid communication with the inlet junction. The substrate processing system includes a flow-regulating orifice having an inlet and an outlet, where the inlet is configured to be coupled to a gas source and the outlet that is in fluid communication with the inlet of the pressure controller.

In another embodiment, a method of processing a substrate in a substrate processing system is provided. The method includes (a) delivering a first flow rate of gas to a first backside gas delivery port coupled to a first substrate support disposed in a first processing volume of a first processing chamber for a first period of time, where delivering the first flow rate of gas having delivering the first flow rate of gas to an inlet junction that is coupled to the first backside gas delivery port through a first inlet valve. The method includes (b) delivering a second flow rate of gas to a second backside gas delivery port coupled to a second substrate support disposed in a second processing volume of a second processing chamber for a second period of time, where. The method includes the second period of time overlaps in time with the first period of time. The method includes delivering the second flow rate of gas having delivering a third flow rate of gas to the inlet junction that is coupled to the second backside gas delivery port through a second inlet valve during the overlap in time of the first and second periods of time, where the third flow rate of gas includes the first flow rate of gas and the second flow rate of gas, and delivering the second flow rate of gas to an inlet junction after the first period of time has elapsed and before the second period of time has elapsed. The method includes where a pressure at the inlet junction while the first flow rate of gas is flowing, the second flow rate of gas is flowing, and the third flow rate of gas is flowing, is maintained at a first pressure.

In another embodiment, a substrate processing system is provided. The substrate processing system includes a first processing chamber having one or more walls defining a first processing volume, a first substrate support disposed in the first processing volume, where the first substrate support having a first backside gas delivery port, a first backside gas conduit having a first end that is in fluid communication with the first backside gas delivery port and a second end that is in fluid communication with a central junction, a first inlet valve disposed between the central junction and an inlet junction, and a first bypass valve disposed between the central junction and a first bypass port, where the first bypass port is in fluid communication with the first processing volume. The substrate processing system includes a second processing chamber having one or more walls defining a second processing volume, a second substrate support disposed in the second processing volume, where the second substrate support having a second backside gas delivery port, a second backside gas conduit having a first end that is in fluid communication with the second backside gas delivery port and a second end that is in fluid communication with a central junction, a second inlet valve disposed between the central junction and the inlet junction, and a second bypass valve disposed between the central junction and a second bypass port, where the second bypass port is in fluid communication with the second processing volume. The substrate processing system includes a pressure controller having an inlet and an outlet, where the pressure controller is configured to maintain a backside gas at about a configurable backside gas pressure, where the outlet of the pressure controller is in fluid communication with the inlet junction. The substrate processing system includes a flow-regulating orifice having an inlet and an outlet, where the inlet is coupled to a gas source and the outlet is in fluid communication with the inlet of the pressure controller. The substrate processing system includes at least one controller having a memory that includes computer-readable instructions stored therein, and the computer-readable instructions, when executed, in real-time, by a processor of the controller, cause a delivery of a first flow rate of gas to a first backside gas delivery port coupled to a first substrate support disposed in a first processing volume of a first processing chamber for a first period of time, where the delivery of the first flow rate of gas having delivering the first flow rate of gas to an inlet junction that is coupled to the first backside gas delivery port through a first inlet valve. The substrate processing system includes a delivery of a second flow rate of gas to a second backside gas delivery port coupled to a second substrate support disposed in a second processing volume of a second processing chamber for a second period of time, where the second period of time overlaps in time with the first period of time, and the delivery of the second flow rate of gas having delivering a third flow rate of gas to the inlet junction that is coupled to the second backside gas delivery port through a second inlet valve during the overlap in time of the first and second periods of time, where the third flow rate of gas includes the first flow rate of gas and the second flow rate of gas, and delivering the second flow rate of gas to an inlet junction after the first period of time has elapsed and before the second period of time has elapsed. The substrate processing system includes where a pressure at the inlet junction while the first flow rate of gas is flowing, the second flow rate of gas is flowing, and the third flow rate of gas is flowing, is maintained at a first pressure.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 illustrates a schematic of a substrate processing system according to an embodiment described herein.

FIG. 2 illustrates a schematic of a backside gas delivery system according to an embodiment described herein.

FIG. 3 illustrates a flow diagram describing a method according to an embodiment described herein.

FIG. 4 illustrates a timing diagram relating to a method of delivering a gas within a substrate processing system, according to an embodiment described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Gas delivery systems play a critical role in semiconductor manufacturing processes. They are responsible for delivering precise quantities and purity of various gases to enable the fabrication of semiconductor devices with high accuracy, reliability, and safety. These complex systems ensure that the necessary gases are delivered in a controlled manner to meet the stringent requirements of semiconductor fabrication processes.

Gas delivery systems in semiconductor manufacturing typically involve complex systems which in gas sources, delivery lines, delivery control modules, purification systems, distribution systems, and monitoring systems. The various systems, modules, and components that form a gas delivery system are both complex and expensive. One such example system is the backside gas delivery system. In physical vapor deposition (PVD) applications, backside gas is delivered to the underside of a clamped substrate to provide for convective heat transfer between the substrate, and the electrostatic chuck. Current backside gas delivery systems are slow, not shareable between processing stations, imprecise, require expensive mass flow controllers, and require manual calibration and service to maintain performance.

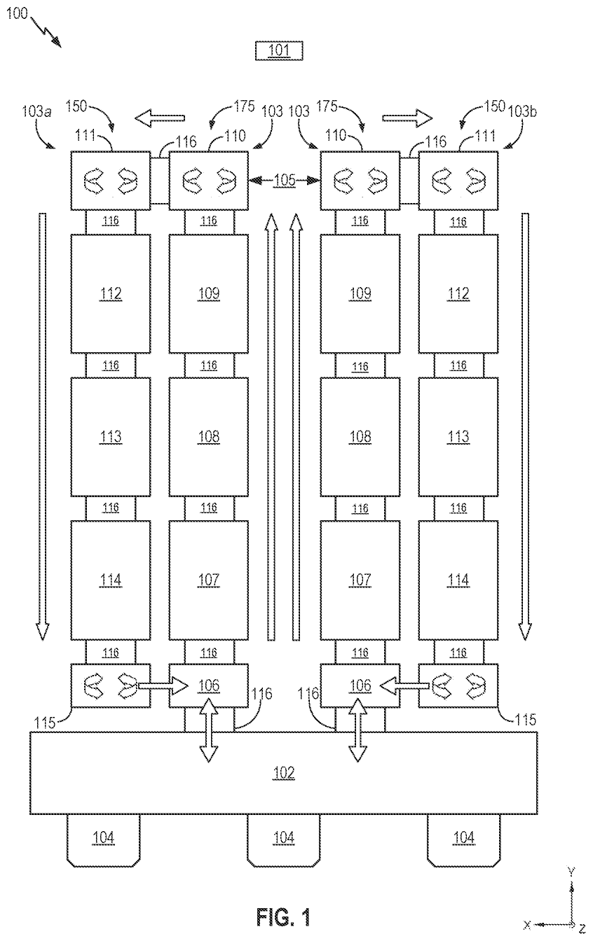

FIG. 1 illustrates a schematic of a substrate processing system 100 that can be used to process a semiconductor substrate in a plurality of process chambers. The substrate processing system 100 includes a controller 101, at least one processing line 103, and a factory interface 102.

As shown, first substrate processing line 103a, and second substrate processing line 103b, collectively referred to as substrate processing line(s) 103, each include a plurality of stations, such as stations 106-115. In some embodiments, each of the processing lines 103 includes a magnetic transportation system (not shown) formed from the individual magnetic levitation assemblies that convey a substrate (not shown) disposed on a substrate carrier (not shown) through the stations 106-115 of the processing line 103. Each of the processing lines 103 is independent of the others. As shown, the processing lines 103 are physically separated from one another by a gap 105. The gap 105 may be sized such that a technician may walk between each of the processing lines 103 to service one or more stations within each of the processing lines 103.

Each processing line 103 may include a plurality of slit valves 116 to selectively isolate each station. The slit valves are selectively opened and closed to allow a clear path for the travel of the substrate carrier (not shown) and to selectively isolate the stations 106-115 from one another and to facilitate the pressurization or depressurization of a station.

The substrate processing system 100 is used to process multiple substrates in each processing line 103 to produce a desired fabricated substrate. For example, the substrate processing system 100 may include a plurality of stations that are configured to perform a physical vapor deposition (PVD) process. For example, the first station 106 is a first load lock, the second station 107 is a degas station, the third station 108 is a pre-clean station, the fourth station 109 is a second pre-clean station, the fifth station 110 is a routing station, the sixth station 111 is a routing station, the seventh station 112 is a PVD tantalum nitride deposition station, the eighth station 113 is a PVD copper deposition station, the ninth station 114 is a second PVD copper deposition station, and the tenth station 115 is a routing station that also serves as a buffer station. The substrate is transferred and processed within each process station 107-109 and 112-114.

Each processing line 103 of the substrate processing system 100 may include at least a first common resource configured to deliver at least a first resource. For example, at least one gas delivery system (not shown) configured to deliver at least one gas resource from at least one common gas resource, or remove a gas from a station, such as provide a gas to achieve an gas pressure greater than about 760 Torr within a station or remove a gas to achieve a vacuum pressure from about 10⁻⁹ Torr to about 760 Torr within a station. In other examples, the first common resource configured to deliver the first resource may include at least one of a common power resource (not shown) to deliver AC or DC power to a station component, or a heat exchanging and heat control system, or any combination thereof. In some embodiments there may be a first common resource, a second common resource, a third common resource, . . . , and an N^{th} common resource, are used to deliver a first resource, a second resource, a third resource, . . . , and an N^{th} resource to the various stations of each processing line 103 of the substrate processing system 100. In other embodiments, the first common resource, the second common resource, the third common resource, . . . , and the N^{th} common resource, to deliver the first resource, the second resource, a third resource, . . . , and the N^{th} resource may be a single common resource.

The at least one gas delivery system may include a gas delivery system configured to deliver a backside gas from a common gas resource to the underside of a substrate positioned in an electrostatic chuck within the processing volume of one or more stations of the substrate processing system 100. The common gas resource may consist of a gas cylinder, gas cylinder bank, tank farm, or bulk gas storage system. The common gas resource may contain and supply various gases required substrate processing such as nitrogen (N₂), oxygen (O₂), hydrogen (H₂), argon (Ar), helium (He), various process gases like silane (SiH₄), dopants, or combination thereof. Typically, the backside gas is an inert gas such as argon, or helium. In other embodiments, the backside gas may differ.

The at least one gas delivery system may include at least one vacuum pump (not shown) to generate a vacuum pressure within the stations 106-115. The vacuum pump (not shown) may be a turbopump, cryopump, roughing pump, or other useful device that is able to maintain a desired vacuum pressure within at least process stations 107-109, and 112-114, load lock of the first station 106, routing stations 110-111, and 115. The magnitude of a vacuum pressure within each station may increase from the first station to the last station within a substrate transfer sequence. For example, the magnitude of the vacuum pressure in the ninth station 114 (e.g., 10⁻⁷ Torr base pressure) may exceed the magnitude of a vacuum pressure in the other stations, such as first station 106 (e.g., 10⁻³ Torr base pressure).

In some embodiments, the first station 106 (e.g., load lock) includes a magnetic levitation assembly (not shown) that includes an array of magnetic levitation actuators (not shown) that are configured to levitate and impart a translational motion to a carrier (not shown) that is configured to support a substrate during a substrate transferring process. The second station 107, the third station 108, fourth station 109, seventh station 112, eighth station 113, and ninth station 114 (e.g., process stations) are also similarly configured.

FIG. 1 includes an X-Y-Z coordinate system to show the direction of travel of the carrier and substrate through the substrate processing system 100. The arrows illustrate the direction that one or more carriers circulate within the processing line 103. The carrier (not shown) receives a substrate entering the first station 106 in the Y-direction from a front opening unified pod (FOUP) 104 of the factory interface 102. The carrier (not shown) is then conveyed to the second station 107 in the Y-direction. The first station 106 also receives the carrier (not shown) from the tenth station 115 in the X-direction. After the carrier (not shown) is conveyed into the second station 107, the carrier (not shown) is conveyed to the fifth station 110 through the third station 108, and the fourth station 109, in the Y-direction. The carrier (not shown) is then conveyed from the fifth station 110 to the sixth station 111 in the negative X-direction. The carrier (not shown) is then conveyed from the sixth station 111 to the tenth station 115 in the negative Y-direction through the process stations 112-114 to the tenth station 115. The carrier (not shown) is then conveyed in the X-direction and back into the first station 106. The now processed substrate (not shown) is transferred to a FOUP 104 of the factory interface 102. Another substrate may be placed onto a carrier positioned in the first station 106 for the processing operation as described above.

In some embodiments of substrate processing system 100, the processing line 103 has a non-deposition portion 175 and a deposition portion 150. The non-deposition portion 175 may include a linear arrangement of stations, such as the first station 106, the second station 107, the third station 108, the fourth station 109, and the fifth station 110, that do not subject the substrate to a process that deposits a layer on the substrate. After the substrate passes through the non-deposition portion 175, the substrate is conveyed into the deposition portion 150 that may be a linear arrangement of stations, such as the sixth station 111, the seventh station 112, the eighth station 113, the ninth station 114, and the tenth station 115 that includes at least one station that deposits at least one layer the substrate. For example, the non-deposition portion 175 includes the first station 106 that is a first load lock, the second station 107 that is a degas station, the third station 108 that is a pre-clean station, the fourth station 109 that is a second pre-clean station, and the fifth station 110 that is a routing station. The deposition portion 150 includes the sixth station 111 that is a routing station, the seventh station 112 that is a PVD tantalum nitride deposition station, the eighth station 113 that is a PVD copper deposition station, the ninth station 114 that is a second copper deposition station, and the tenth station 115 that is a routing station that also serves as a buffer station.

In some embodiments, the stations of the non-deposition portion 175, such as the second station 107, the third station 108, or the fourth station 109, may each respectively be a degas station, pre-clean station, pre-heating station, annealing station, cool down station, or any other suitable substrate processing station. In some embodiments, the stations of the deposition portion 150, such as the seventh station 112, the eighth station 113, and the ninth station 114, may each respectively be a tantalum nitride deposition station, copper deposition station, etching station, or any deposition station that deposits at least one layer on the substrate. In the example provided in FIG. 1, the stations of the deposition portion 150 utilize PVD. In other embodiments, one or more of the stations of the deposition portion 150 of the substrate processing system may utilize PVD, chemical vapor deposition (CVD), atomic layer deposition (ALD), or any combination thereof.

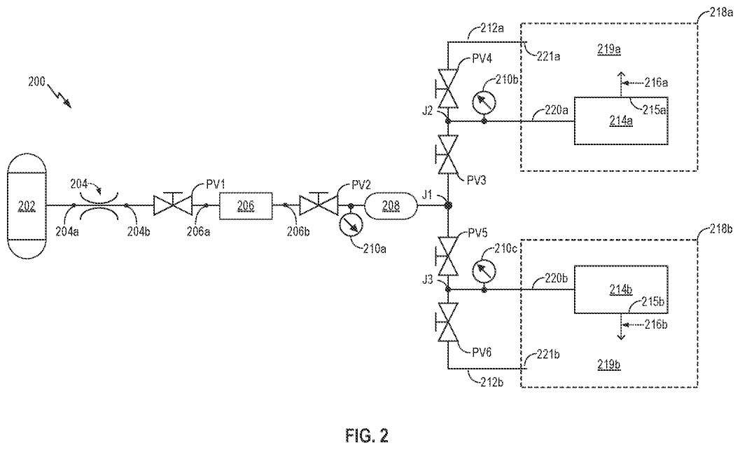

FIG. 2 illustrates a schematic of a backside gas delivery system 200 according to one embodiment. The backside gas delivery system 200 is configured to deliver a backside gas to one or more backside gas delivery ports 215 of electrostatic chucks disposed within the processing volumes 219 of one or more stations of one or more substrate processing lines of a substrate processing system. In this embodiment, the backside gas delivery system 200 illustrates two processing chambers 218, a first processing chamber 218a of the first station of the first substrate processing line 103a, and a second processing chamber 218b of the of the first station of the second substrate processing line 103b.

The first processing chamber 218a includes one or more walls defining a first processing volume 219a. The second processing chamber 218b includes one or more walls defining a second processing volume 219b. In some embodiments, the first processing chamber 218a may be within one or more stations of the first substrate processing line 103a. In some embodiments, the second processing chamber 218b may be within one or more stations of the second substrate processing line 103b. In other embodiments, additional processing volumes, processing chambers, additional stations, and/or additional processing lines may be present.

The backside gas delivery system 200 includes a gas source 202. The gas source 202 is configured to deliver the backside gas to the rest of the backside gas delivery system 200. The gas source 202 may consist of a gas cylinder, gas cylinder bank, tank farm, or bulk gas storage system. The gas source 202 includes at least one output. The gas source 202 may include features like gas monitoring, leak detection, and safety interlocks to prevent accidents. The common gas resource may include 202 nitrogen (N₂), oxygen (O₂), hydrogen (H₂), argon (Ar), helium (He), various process gases like silane (SiH₄), dopants, or a combination thereof. Typically, the backside gas is argon. In other embodiments, the backside gas may differ.

The backside gas delivery system 200 includes a flow-regulating orifice 204. The flow-regulating orifice 204 includes an input 204a, and an output 204b. The input 204a of the flow-regulating orifice 204 is coupled to at least one output of the gas source 202. The flow-regulating orifice 204 may be of any suitable configuration, including, but not limited to, a fixed orifice tube, an adjustable orifice tube, a variable orifice tube, a proportional control orifice tube, a critical orifice tube, or combination thereof. The flow-regulating orifice 204 acts as a flow restrictor by creating a pressure drop across the orifice, which in turn determines the flow rate of the gas. By selecting the diameter of the passageway through the flow-regulating orifice 204, a configurable flow rate for a particular gas and application can be achieved. The configurable flow rate may be between about 2 standard cubic centimeters per minute (SCCM) to about 100 SCCM. For example, the flow rate may be about 40 SCCM. For example, the flow rate may be about 50 SCCM.

The backside gas delivery system 200 includes a valve PV1. Valve PV1 includes an input, and output. The input of valve PV1 is coupled to the output of the flow-regulating orifice 204. Valve PV1 may be of any suitable type including, but not limited to, a gate valve, butterfly valve, ball valve, needle valve, angle valve, poppet valve, diaphragm valve, solenoid valve, check valve, or combination thereof, depending on factors such as the specific application, pressure range, flow rate, material compatibility, desired level of sealing, gas composition, or other system design considerations. Valve PV1 may be operated manually, pneumatically, mechanically, electronically, electromechanically, by a pilot source, or combination thereof. Valve PV1 is configured to enable, or halt, the delivery of a fluid or gas, for example, the backside gas. In other embodiments, valve PV1 may not be present.

The backside gas delivery system 200 includes a pressure controller 206. The pressure controller 206 includes an inlet 206a, and an outlet 206b. The inlet 206a of the pressure controller 206 is coupled to the output of valve PV1. In other embodiments, the 206a of the pressure controller may be coupled to the output 204b of the flow-regulating orifice 204. The pressure controller 206 may be of any suitable type, such as a manual pressure controller, electronic pressure controller, proportional-integral-derivative (PID) controller, pneumatic controller, or combination thereof. The pressure controller 206, if so equipped, may accept any suitable input for pressure-sensing and feedback, for example, from a combination of one or more internal or external pressure-sensing elements 210, or controller 101, or combination thereof. The pressure controller 206 may operate autonomously or through communication from an external source, such as controller 101. The pressure controller 206 may operate with feedback (e.g., closed-loop) or without feedback (e.g., open-loop). The pressure controller 206 may include various complementary sub-components, such as, internal or external, regulators, valves, orifice tubes (both fixed or variable), solenoids, controllers, or combinations thereof, to achieve precise pressure control. The pressure controller 206 operates to regulate and maintain a configurable backside gas pressure within the backside gas delivery system 200 by transmitting signaling to one or more connected devices. For example, the pressure controller 206 may receive input data from an internal pressure sensor, and based on that information, transmit signaling to the variable orifice controller to change the orifice size of a variable orifice element to regulate and maintain the configurable backside gas pressure within the backside gas delivery system 200.

The configurable backside gas pressure is between about 1 Torr and about 20 Torr at one or both of the backside delivery ports 215a, 215b at an instant in time. For example, the configurable backside gas pressure is about 7 Torr at the first backside delivery port 215a during a first period time, and is also about 7 Torr at the second backside delivery port 215b during a second period of time, wherein, in this example, the first and second periods of time do not overlap. For example, the configurable backside gas pressure is about 10 Torr at both of the backside delivery ports 215a, 215b during overlapping or non-overlapping processing of substrates in their respective processing chambers.

The backside gas delivery system 200 includes a valve PV2. Valve PV2 includes an input, and output. The input of valve PV2 is coupled to the outlet 206b of the pressure controller 206. Valve PV2 may be of any suitable type including, but not limited to, a gate valve, butterfly valve, ball valve, needle valve, angle valve, poppet valve, diaphragm valve, solenoid valve, check valve, or combination thereof, depending on factors such as the specific application, pressure range, flow rate, material compatibility, desired level of sealing, gas composition, or other system design considerations. Valve PV2 may be operated manually, pneumatically, mechanically, electronically, electromechanically, by a pilot source, or combination thereof. Valve PV2 is configured to enable, or halt, the delivery of a fluid or gas, for example, the backside gas. In other embodiments, valve PV2 may not be present.

The backside gas delivery system 200 includes an accumulator 208. The accumulator 208 includes an input and an output. The input of the accumulator 208 is coupled to output of valve PV2. The output of the accumulator 208 is coupled to an inlet junction J1. The accumulator 208, also commonly known as a pressure reservoir, surge tank, or buffer tank, acts to stabilize pressure in the backside gas delivery system 200 acting a buffer for pressure fluctuations and/or serving as storage during temporary gas supply interruptions. The accumulator may be of any suitable type, including, but not limited to, piston accumulators, diaphragm accumulators, bladder accumulators, gas spring accumulators, or combination thereof. The accumulator 208 is optional, and in some embodiments, no accumulator 208 may be present. In other embodiments, the accumulator 208 may be disposed, and coupled, in another location of the backside gas delivery system 200. In yet other embodiments, more than one accumulator 208 may be present.

The backside gas delivery system 200 also includes a first pressure-sensing element 210a capable to measure, and communicate, a backside gas pressure. The first pressure-sensing element 210a is disposed between outlet 206b of the pressure controller 206 and the inlet junction J1. When present, the first pressure-sensing element 210a may be disposed before the accumulator 208 or after the accumulator 208. In other embodiments, other pressure-sensing elements 210 may be disposed in other locations of the backside gas delivery system 200. The first pressure-sensing element 210a may be of any suitable type, analog or digital, an may utilize any suitable pressure-sensing element such as a bourdon tube, strain gauge, capacitive sensor, optical, vibrating element, or piezoelectric sensor. The first pressure-sensing element 210a may be in communication with one or more elements, such as the pressure controller 206, and/or controller 101.

The backside gas delivery system 200 includes a first inlet valve PV3. The first inlet valve PV3 includes an input, and output. The input of the first inlet valve PV3 is coupled to the inlet junction J1. The output of the first inlet valve PV3 is coupled to a central second junction J2. The first inlet valve PV3 may be of any suitable type including, but not limited to, a gate valve, butterfly valve, ball valve, needle valve, angle valve, poppet valve, diaphragm valve, solenoid valve, check valve, or combination thereof, depending on factors such as the specific application, pressure range, flow rate, material compatibility, desired level of sealing, gas composition, or other system design considerations. The first inlet valve PV3 may be operated manually, pneumatically, mechanically, electronically, electromechanically, by a pilot source, or combination thereof. The first inlet valve PV3 is configured to enable, or halt, the delivery of a fluid or gas, for example, the backside gas.

The backside gas delivery system 200 includes a bypass valve PV4. Bypass valve PV4 includes an input, and output. The input of bypass valve PV4 is coupled to the central second junction J2. The bypass valve PV4 may be of any suitable type including, but not limited to, a gate valve, butterfly valve, ball valve, needle valve, angle valve, poppet valve, diaphragm valve, solenoid valve, check valve, or combination thereof, depending on factors such as the specific application, pressure range, flow rate, material compatibility, desired level of sealing, gas composition, or other system design considerations. Bypass valve PV4 may be operated manually, pneumatically, mechanically, electronically, electromechanically, by a pilot source, or combination thereof. Bypass valve PV4 is configured to enable, or halt, the delivery of a fluid or gas, for example, the backside gas.

The first processing volume 219a of the first station of the first substrate processing line 103a includes a first substrate support 214a. The first substrate support 214a is configured to securely hold and immobilize, by physical or electrostatic force, the substrate during various processes. The first substrate support 214a may also include vacuum channels or grooves to aid in the removal of air trapped between the clamping surface of the chuck and the substrate thereby facilitating better contact and enhanced electrostatic force.

The first substrate support 214a includes a first backside gas delivery port 215a to supply the backside gas to channels or grooves emptying to the underside of a loaded substrate secured in the first substrate support 214a. The backside gas conduit 220a includes a first end in fluid communication with the central junction J2, and a second end in fluid communication with a first backside gas delivery port 215a. When the backside gas is supplied to a backside gas port that is disposed under the backside of a loaded substrate, a portion of the supplied backside gas, represented by backside gas flow 216a, escapes from the underside of the loaded substrate into the first processing volume 219a of the first station of the first substrate processing line 103a.

The first processing volume 219a of the first station of the first substrate processing line 103a additionally includes a processing chamber bleed line (PCBL) 212a. The PCBL 212a has an input, and an output. The input of the PCBL 212a is coupled to the output of bypass valve PV4. The output of the PCBL 212 is coupled to a first bypass port 221a of the first processing volume 219a of the first station of the first substrate processing line 103a. The PCBL 212a is configured so that when bypass valve PV4 is opened, gas may flow through the bypass valve PV4 and the PCBL 212a allowing the backside gas inside the backside gas conduit 220a to vent through the PCBL 212a, the first bypass port 221a, and into the first processing volume 219a of the first station of the first substrate processing line 103a. The PCBL 212a gas conduit is of suitable size (e.g., pipe conductance) to vent the first processing volume 219a within a configurable time period. For example, the PCBL 212a may have an inner diameter between about 7 millimeters (mm) and about 35 mm. For example, the PCBL 212a gas conduit may have an inner diameter of about 15 mm. For example, the PCBL 212a gas conduit may have an inner diameter of about 25 mm.

The backside gas delivery system 200 also includes a second pressure-sensing element 210b capable to measure and communicate a backside gas pressure. The pressure-sensing element 210 is disposed along, and coupled to, the gas delivery system after the first inlet valve PV3, and before bypass valve PV4. For example, the second pressure-sensing element 210b may be coupled to the output of the first inlet valve PV3. For example, the second pressure-sensing element 210b may be coupled to the input of bypass valve PV4. For example, the second pressure-sensing element 210b may be coupled to the central second junction J2. For example, the second pressure-sensing element 210b may be coupled to the backside gas conduit 220a. The second pressure-sensing element 210b may be of any suitable type, analog or digital, an may utilize any suitable pressure-sensing element such as a bourdon tube, strain gauge, capacitive sensor, optical, vibrating element, or piezoelectric sensor. The second pressure-sensing element 210b may be in communication with one or more elements, such as the pressure controller 206, and/or controller 101.

The backside gas delivery system 200 includes an inlet valve PV5. Inlet valve PV5 includes an input, and output. The input of inlet valve PV5 is coupled to the inlet junction J1. The output of inlet valve PV5 is coupled to a central second junction J2. The inlet valve PV5 may be of any suitable type including, but not limited to, a gate valve, butterfly valve, ball valve, needle valve, angle valve, poppet valve, diaphragm valve, solenoid valve, check valve, or combination thereof, depending on factors such as the specific application, pressure range, flow rate, material compatibility, desired level of sealing, gas composition, or other system design considerations. Inlet valve PV5 may be operated manually, pneumatically, mechanically, electronically, electromechanically, by a pilot source, or combination thereof. Inlet valve PV5 is configured to enable, or halt, the delivery of a fluid or gas, for example, the backside gas.

The backside gas delivery system 200 includes a bypass valve PV6. Bypass valve PV6 includes an input, and output. The input of bypass valve PV6 is coupled to the central second junction J2. The bypass valve PV6 may be of any suitable type including, but not limited to, a gate valve, butterfly valve, ball valve, needle valve, angle valve, poppet valve, diaphragm valve, solenoid valve, check valve, or combination thereof, depending on factors such as the specific application, pressure range, flow rate, material compatibility, desired level of sealing, gas composition, or other system design considerations. Bypass valve PV6 may be operated manually, pneumatically, mechanically, electronically, electromechanically, by a pilot source, or combination thereof. Bypass valve PV6 is configured to enable, or halt, the delivery of a fluid or gas, for example, the backside gas.

The second processing volume 219b of the first station of the second substrate processing line 103b includes a second substrate support 214b. The second substrate support 214b is configured to securely hold and immobilize, by physical or electrostatic force, the substrate during various processes. The second substrate support 214b may also include vacuum channels or grooves to aid in the removal of air trapped between the clamping surface of the chuck and the substrate thereby facilitating better contact and enhanced electrostatic force.

The second substrate support 214b includes a second backside gas delivery port 215b to supply the backside gas to channels or grooves emptying to the underside of a loaded substrate secured in the second substrate support 214b. The backside gas conduit 220b includes a first end in fluid communication with the central junction J2, and a second end in fluid communication with a second backside gas delivery port 215b. When the backside gas is supplied to the backside delivery port disposed under the backside of a loaded substrate, a portion of the supplied backside gas, represented as a backside gas flow 216b, escapes from the underside of the loaded substrate into the second processing volume 219b of the first station of the second substrate processing line 103b.

The second processing volume 219b of the first station of the second substrate processing line 103b additionally includes a processing chamber bleed line (PCBL) 212b. The PCBL 212b has an input, and an output. The input of the PCBL 212b is coupled to the output of bypass valve PV6. The output of the PCBL 212b is coupled to a second bypass port 221b of the second processing volume 219b of the first station of the second substrate processing line 103b. The PCBL 212b is configured so that when bypass valve PV6 is opened, gas may flow through the bypass valve PV6 and the PCBL 212b allowing the backside gas inside the backside gas conduit 220b to vent through the PCBL 212b, the second bypass port 221b, and into the second processing volume 219b of the first station of the second substrate processing line 103b. The PCBL 212b gas conduit is of suitable size (e.g., pipe conductance) to vent the second processing volume 219b within a configurable time period. For example, the PCBL 212b may have an inner diameter between about 7 millimeters (mm) and about 35 mm. For example, the PCBL 212b gas conduit may have an inner diameter of about 15 mm. For example, the PCBL 212b gas conduit may have an inner diameter of about 25 mm.

The backside gas delivery system 200 also includes a third pressure-sensing element 210c. The third pressure-sensing element 210c is disposed along, and coupled to, the gas delivery system after inlet valve PV5, and before bypass valve PV6. For example, the third pressure-sensing element 210c may be coupled to the output of inlet valve PV5. For example, the third pressure-sensing element 210c may be coupled to the input of bypass valve PV6. For example, the third pressure-sensing element 210c may be coupled to the central second junction J2. For example, the third pressure-sensing element 210c may be coupled to the backside gas conduit 220b. The third pressure-sensing element 210c may be of any suitable type, analog or digital, an may utilize any suitable pressure-sensing element such as a bourdon tube, strain gauge, capacitive sensor, optical, vibrating element, or piezoelectric sensor. The third pressure-sensing element 210c may be in communication with one or more elements, such as the pressure controller 206, and/or controller 101.

In other embodiments, additional valves, regulators, and similar components, may be disposed, and coupled, in additional locations in the backside gas delivery system 200 as required.

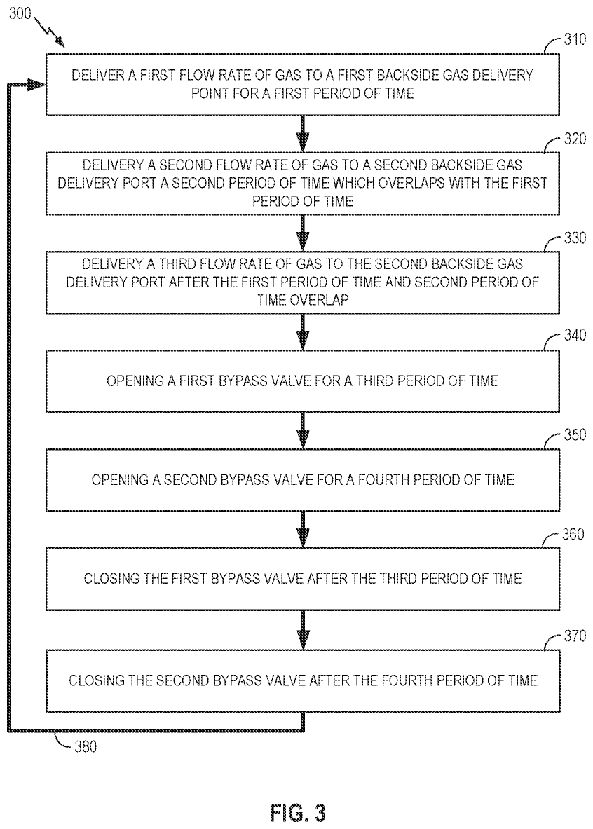

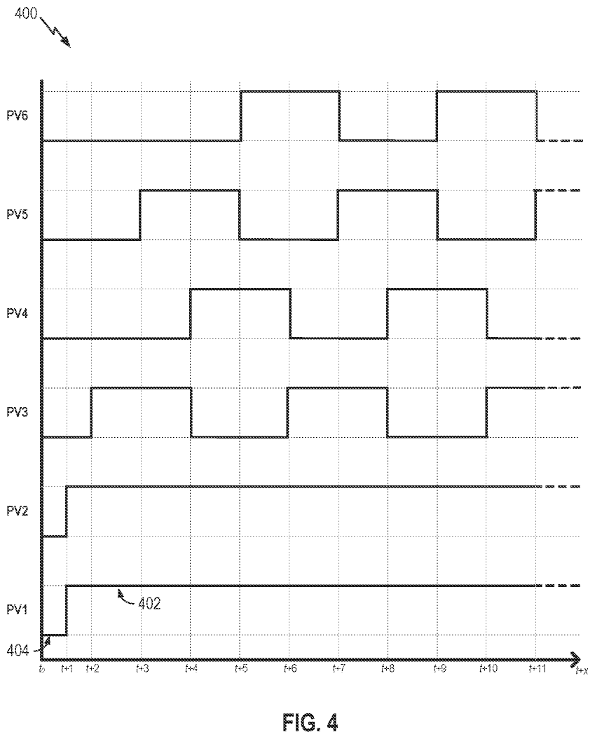

FIG. 3 illustrates a method 300 for sharing a resource, such as sharing a common gas resource, vacuum pump, or other useful resource, in a substrate processing system according to one embodiment. Method 300, as described below, may be best understood with reference to FIG. 2, and FIG. 4.

While the operations of method 300 are described in a linear manner in the flow diagram shown in FIG. 3. As implemented, the operations of method 300 may occur simultaneously, may overlap in time, and may be repeated individually, or as a whole. Further, while only two substrates, a first substrate and second substrate, are focused on in this example of method, as implemented, a plurality of substrates will be simultaneously moving one-after-another through the substrate processing system 100 at any given time.

FIG. 4 illustrates a timing diagram 400 that is used to illustrate operations performed during the performance of method 300. The timing diagram shows one possible configuration for valve timing for a gas delivery system, such as backside gas delivery system 200. FIG. 4 has two axes, a horizontal axis showing an the passage of time from t₀ to t+x, and a vertical axis showing the state of six valves over the period of time. The state of each valve, such as an open (a high-state 402) or a closed (a low-state) of valve PV1, valve PV2, the first inlet valve PV3, the first bypass valve PV4, the second inlet valve PV5, and the second bypass valve PV6 are illustrated in FIG. 4.

Using the backside gas delivery system 200 shown in FIG. 2 as an example, at to, the timing diagram begins with all six valves closed. At t+1, valve PV1 and valve PV2 open. The remaining valves, the first inlet valve PV3, the first bypass valve PV4, the second input valve PV5, and the second bypass valve PV6 remain closed. Opening valve PV1 and PV2 allows gas to flow from gas source 202 through flow-regulating orifice 204, valve PV1, pressure controller 206, valve PV2, accumulator 208, to the inlet junction J1 and to the closed first inlet valve PV3, and second inlet valve PV5. Valve PV1 and valve PV2 will remain open to, and past, t+x, until gas from the gas source 202 is no longer required.

Operation 310 of method 300 includes delivering a first flow rate of gas to a first backside gas delivery port 215a coupled to a first substrate support 214a disposed in a first processing volume 219a of a first processing chamber 218a for a first period of time (e.g. t+2 through t+4). Delivering the first flow rate of includes delivering the first flow rate of gas to an inlet junction J1 that is coupled to the first backside gas delivery port 215a through a first inlet valve PV3.

Referring to timing diagram 400 in FIG. 4, at t+2, first inlet valve PV3 opens while the first bypass valve PV4, the second inlet valve PV5, and the second bypass valve PV6 remain closed. Opening the first inlet valve PV3 allows gas to flow from the inlet junction J1, and through the first inlet valve PV3, the central junction J2, the backside gas conduit 220a, and past second pressure-sensing element 210b, to the first backside gas delivery port 215a of the first substrate support 214a disposed in the first processing volume 219a of the first processing chamber 218a.

Operation 320 of method 300 includes delivering a second flow rate of gas to a second backside gas delivery port 215b coupled to a second substrate support 214b disposed in a second processing volume 219b of a second processing chamber 218b for a second period of time (e.g. t+3 through t+5).

Referring to timing diagram 400 in FIG. 4, at t+3, second inlet valve PV5 opens. The first bypass valve PV4, and the second bypass valve PV6 remain closed. Opening the second inlet valve PV5 allows gas to additionally flow from the inlet junction J1, and then through second inlet valve PV5, the central junction J3, the backside gas conduit 220b, the third pressure-sensing element 210c, to the second backside gas delivery port 215b of the second substrate support 214b disposed in the second processing volume 219b of the second processing chamber 218b.

During the overlap in time of the first and second periods of time (e.g., t+3 through t+4), operation 330 of method 300 includes delivering a third flow rate of gas to the inlet junction J1 that is coupled to the first backside gas delivery port 215a through the first inlet valve PV3 and the second backside gas delivery port 215b through the second inlet valve PV5. The third flow rate of gas to the inlet junction J1 includes the first flow rate of gas plus the second flow rate of gas.

During the periods of time where the first flow rate of gas is flowing, the second flow rate of gas is flowing, and the third rate of gas is flowing, the pressure at the inlet junction J1 is maintained at a first pressure by use of the pressure controller 206. The first pressure is between about 3 Torr and about 20 Torr. The first pressure is maintained within a first pressure tolerance, wherein the first pressure tolerance is between about plus or minus 1 Torr from the first pressure.

In some embodiments, maintaining the pressure at the inlet junction J1 at the first pressure within the first pressure tolerance, while the first flow rate of gas is flowing, the second flow rate of gas is flowing, and both the third rate of gas is flowing, is controlled while delivering the first flow rate, the second flow rate, and the third flow rates of gas from the gas source 202 through pressure controller 206 and the inlet junction J1. Maintaining the first pressure within the first pressure tolerance at the first junction J1 includes the pressure controller 206 adjusting the first pressure at the inlet junction J1 based upon one or more signals. The one or more signals can include receiving a signal corresponding to a measured pressure from a first pressure-sensing element 210a disposed between the pressure controller and the inlet junction, receiving a signal corresponding to a measured pressure from a second pressure-sensing element 210b disposed between the first inlet valve PV3 and the first backside gas delivery port 215a of the first processing chamber 218a, receiving a signal corresponding to a measured pressure from a third pressure-sensing element 210c disposed between the second inlet valve PV5 and the second backside gas delivery port 215b of the second processing chamber 218b, or any combination thereof. In one example, a substantially constant pressure is provided at the inlet junction J1 while the first flow rate, second flow rate, and third rate of gas is flowing generally includes controlling the pressure at the inlet junction J1 within a tolerance of less than 10% full scale pressure provided by the gas source 202, such as less than 5% full scale, such as less than 2% full scale, such as less than 1% full scale, such as less than 0.5% full scale, such as less than 0.2% full scale, and even such as less than 0.1% full scale.

Operation 340 of method 300 includes closing the first inlet valve PV3 when the first period of time has elapsed (e.g., t+2 through t+4), and opening a first bypass valve PV4 for a third period of time (e.g., t+4 through t+6). Referring to timing diagram 400 in FIG. 4, at t+4, the first inlet valve PV3 closes and the first bypass valve PV4 opens. The first bypass valve PV4 is coupled between the first backside gas delivery port 215a and a first bypass port 221a, which is in communication with the first processing volume 219a of the first processing chamber 218a. Opening the first bypass valve PV4 allows the gas within the backside gas conduit 220a to vent through the central junction J2, the first bypass valve PV4, PCBL 212a, and the first bypass port 221a, into to the first processing volume 219a of the first processing chamber 218a.

Operation 350 of method 300 includes closing the second inlet valve PV5 when the second period of time has elapsed (e.g. t+3 through t+5), and opening a second bypass valve PV5 for a fourth period of time (e.g. t+5 through t+7). Referring to timing diagram 400 in FIG. 4, at t+5, the second inlet valve PV5 closes and the second bypass valve PV6 opens. The second bypass valve PV6 is coupled between the second backside gas delivery port 215b and a second bypass port 221b, which is in communication with the second processing volume 219b of the second processing chamber 218B. Opening the second bypass valve PV6 allows the gas within the backside gas conduit 220b to vent through the central junction J3, the second bypass valve PV6, PCBL 212b, and the second bypass port 221b, into to the second processing volume 219b of the second processing chamber 218b.

Operation 360 of method 300 includes closing the first bypass valve PV4 after the third period of time (e.g., t+4 through t+6) has elapsed and repeating operation 310 of method 300. Referring to timing diagram 400 in FIG. 4, at t+6, the first bypass valve PV4 closes and the first input valve PV3 opens for the first period of time (e.g., t+6 through t+8).

Operation 370 of method 300 includes closing the second bypass valve PV6 after the fourth period of time (e.g., t+5 through t+7) has elapsed and repeating operation 320 of method 300. Referring to timing diagram 400 in FIG. 4, at t+7, the second bypass valve PV6 closes and the second input valve PV5 opens for the second period of time (e.g., t+7 through t+9).

At operation 380 of method 300, the one or more of the previous operations 310-370 of method 300 may be repeated as required. For example, in FIG. 4, at t+9, the operations taken from t+2 through t+9 may be repeated and continue past t+x as required.

### Additional Considerations

While this specification contains many specific implementation details, these should not be construed as limitations on the scope of what may be claimed, but rather as descriptions of features that may be specific to particular implementations. Certain features that are described in this specification in the context of separate implementations may also be implemented, in combination, in a single implementation. Conversely, various features that are described in the context of a single implementation may also be implemented in multiple implementations, separately, or in any suitable sub-combination. Moreover, although previously described features may be described as acting in certain combinations and even initially claimed as such, one or more features from a claimed combination may, in some cases, be excised from the combination, and the claimed combination may be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional) to achieve desirable results. In certain circumstances, multitasking or parallel processing (or a combination of multitasking and parallel processing) may be advantageous and performed as deemed appropriate. While the various steps in an embodiment method or process are presented and described sequentially, one of ordinary skill in the art will appreciate that some or all of the steps may be executed in different order, may be combined, or omitted, and some or all of the steps may be executed in parallel. The steps may be performed actively or passively. The method or process may be repeated or expanded to support multiple components or multiple users within a field environment. Accordingly, the scope should not be considered limited to the specific arrangement of steps shown in a flowchart or diagram.

Furthermore, any claimed implementation is considered to be applicable to at least a computer-implemented method; a non-transitory, computer-readable medium storing computer-readable instructions to perform the computer-implemented method; and a computer system including a computer memory interoperability coupled with a hardware processor configured to perform the computer-implemented method or the instructions stored on the non-transitory, computer-readable medium.

As used herein, “a CPU”, “controller”, “a processor”, “at least one processor”, or “one or more processors”, generally refers to a single processor configured to perform one or multiple operations or multiple processors configured to collectively perform one or more operations. In the case of multiple processors, performance the one or more operations could be divided amongst different processors, though one processor may perform multiple operations, and multiple processors could collectively perform a single operation. Similarly, “a memory”, at least one memory”, or “one or more memories”, generally refers to a single memory configured to store data and/or instructions, multiple memories configured to collectively store data and/or instructions.

As used herein, “gas” and “fluid” may be used interchangeable with either term generally referring to elements, compounds, materials, etc., having the properties of a gas, a fluid, or both a gas and a fluid.

Unless defined otherwise, all technical and scientific terms used have the same meaning as commonly understood by one of ordinary skill in the art to which these systems, apparatuses, methods, processes and compositions belong.

In this disclosure, the terms “top”, “bottom”, “side”, “above”, “below”, “up”, “down”, “upward”, “downward,” “horizontal,” “vertical,” and the like do not refer to absolute directions. Instead, these terms refer to directions relative to a nonspecific plane of reference. This non-specific plane of reference may be vertical, horizontal, or other angular orientation.

The singular forms “a”, “an”, and “the”, include plural referents, unless the context clearly dictates otherwise. Within a claim, reference to an element in the singular is not intended to mean “one and only one” unless specifically so stated, but rather “one or more”. Unless specifically stated otherwise, the term “some” refers to one or more.

Embodiments of the present disclosure may suitably “comprise”, “consist”, or “consist essentially of”, the limiting features disclosed, and may be practiced in the absence of a limiting feature not disclosed. As used here and in the appended claims, the words “comprise”, “has”, and “include”, and all grammatical variations thereof are each intended to have an open, non-limiting meaning that does not exclude additional elements or steps.

“Optional” and “optionally” means that the subsequently described material, event, or circumstance may or may not be present or occur. The description includes instances where the material, event, or circumstance occurs and instances where it does not occur.

“Coupled” and “coupling” means that the subsequently described material is connected to previously described material. The connection may be a direct, or indirect connection, and may, or may not, include intermediary components such as plumbing, wiring, fasteners, mechanical power transmission, electrical communication, wired and/or wireless transmission, etc., which may suitable to affect operation of the components.

As used, the term “determining” encompasses a wide variety of actions. For example, “determining” may include calculating, computing, processing, deriving, investigating, looking up, for example, looking up in a table, a database, or another data structure, and ascertaining. In addition, “determining” may include receiving, for example, receiving information, and accessing, for example, accessing data in a memory. In addition, “determining” may include resolving, selecting, choosing, and establishing.

When the word “approximately” or “about” are used, this term may mean that there may be a variance in value of up to ±10%, of up to 5%, of up to 2%, of up to 1%, of up to 0.5%, of up to 0.1%, or up to 0.01%.

Ranges may be expressed as from about one particular value to about another particular value, inclusive. When such a range is expressed, it is to be understood that another embodiment is from the one particular value to the other particular value, along with all particular values and combinations thereof within the range.

As used, terms such as “first” and “second” are arbitrarily assigned and are merely intended to differentiate between two or more components of a system, an apparatus, or a composition. It is to be understood that the words “first” and “second” serve no other purpose and are not part of the name or description of the component, nor do they necessarily define a relative location or position of the component. Furthermore, it is to be understood that that the mere use of the term “first” and “second” does not require that there be any “third” component, although that possibility is envisioned under the scope of the various embodiments described.

Although only a few example embodiments have been described in detail, those skilled in the art will readily appreciate that many modifications are possible in the example embodiments without materially departing from the disclosed scope as described. Accordingly, all such modifications are intended to be included within the scope of this disclosure as defined in the following claims. In the claims, means-plus-function clauses are intended to cover the structures described as performing the recited function and not only structural equivalents, but also equivalent structures. It is the express intention of the applicant not to invoke 35 U.S.C. § 112(f), for any limitations of any of the claims, except for those in which the claim expressly uses the words ‘means for’ together with an associated function.

The following claims are not intended to be limited to the embodiments provided but rather are to be accorded the full scope consistent with the language of the claims.

What is claimed is:

1. A substrate processing system, comprising:
a first processing chamber comprising:
one or more walls defining a first processing volume;
a first substrate support disposed in the first processing volume, wherein the first substrate support comprises a first backside gas delivery port;
a first backside gas conduit having a first end that is in fluid communication with the first backside gas delivery port and a second end that is in fluid communication with a central junction;
a first inlet valve disposed between the central junction and an inlet junction; and
a first bypass valve disposed between the central junction and a first bypass port, wherein the first bypass port is in fluid communication with the first processing volume;
a second processing chamber comprising:
one or more walls defining a second processing volume;
a second substrate support disposed in the second processing volume, wherein the second substrate support comprises a second backside gas delivery port;
a second backside gas conduit having a first end that is in fluid communication with the second backside gas delivery port and a second end that is in fluid communication with a central junction;
a second inlet valve disposed between the central junction and the inlet junction; and
a second bypass valve disposed between the central junction and a second bypass port, wherein the second bypass port is in fluid communication with the second processing volume;
a pressure controller comprising an inlet and an outlet, wherein the outlet of the pressure controller is in fluid communication with the inlet junction; and
a flow-regulating orifice comprising an inlet and an outlet, wherein the inlet is configured to be coupled to a gas source and the outlet that is in fluid communication with the inlet of the pressure controller.

2. The substrate processing system of claim 1, further comprising an accumulator disposed between the outlet of the pressure controller and the inlet junction, wherein the accumulator is configured to stabilize a configurable backside gas pressure in a backside gas delivery system.

3. The substrate processing system of claim 1, wherein the flow-regulating orifice is configured to deliver a gas at a configurable flow rate, wherein the configurable flow rate is between about 2 standard cubic centimeters per minute (SCCM) to about 100 SCCM.

4. The substrate processing system of claim 1, wherein the first inlet valve, the second inlet valve, the first bypass valve, and the second bypass valve, are each individually configured to enable a delivery of a gas, or halt the delivery of the gas, based upon a signaling from the pressure controller.

5. The substrate processing system of claim 1, further comprising an accumulator, wherein the accumulator is disposed between the pressure controller and the inlet junction.

6. The substrate processing system of claim 1, wherein the pressure controller is configured to deliver, and maintain, a gas at a configurable backside gas pressure, wherein the configurable backside gas pressure is between about 1 Torr and about 20 Torr.

7. A method of processing a substrate in a substrate processing system, comprising:
(a) delivering a first flow rate of gas to a first backside gas delivery port coupled to a first substrate support disposed in a first processing volume of a first processing chamber for a first period of time, wherein delivering the first flow rate of gas comprises:
delivering the first flow rate of gas to an inlet junction that is coupled to the first backside gas delivery port through a first inlet valve; and
(b) delivering a second flow rate of gas to a second backside gas delivery port coupled to a second substrate support disposed in a second processing volume of a second processing chamber for a second period of time, wherein
the second period of time overlaps in time with the first period of time, and
delivering the second flow rate of gas comprises:
delivering a third flow rate of gas to the inlet junction that is coupled to the second backside gas delivery port through a second inlet valve during the overlap in time of the first and second periods of time, wherein the third flow rate of gas includes the first flow rate of gas and the second flow rate of gas, and
delivering the second flow rate of gas to an inlet junction after the first period of time has elapsed and before the second period of time has elapsed;
wherein a pressure at the inlet junction while the first flow rate of gas is flowing, the second flow rate of gas is flowing, and the third flow rate of gas is flowing, is maintained at a first pressure.

8. The method of claim 7, wherein
the pressure at the inlet junction, while the first flow rate of gas is flowing, the second flow rate of gas is flowing, and the third flow rate of gas is flowing, is maintained at the first pressure by use of a pressure controller,
wherein the pressure controller and an orifice are disposed between a gas source and the inlet junction.

9. The method of claim 7, further comprising:
closing the first inlet valve when the first period of time has elapsed; and
opening a first bypass valve for a third period of time when the first period of time has elapsed,
wherein the first bypass valve is coupled between the first backside gas delivery port and a first bypass port, which is in communication with the first processing volume of the first processing chamber.

10. The method of claim 9, further comprising:
closing the second inlet valve when the second period of time has elapsed; and
opening a second bypass valve for a fourth period of time when the second period of time has elapsed,
wherein the second bypass valve is coupled between the second backside gas delivery port and a second bypass port, which is in communication with the second processing volume of the second processing chamber.

11. The method of claim 10, further comprising:
repeating (a) and (b) at least one more time; and
opening the first inlet valve and closing the first bypass valve when the third period of time has elapsed and the first flow rate of gas of the repeated (a) is initiated.

12. The method of claim 11, further comprising:
opening the second inlet valve and closing the second bypass valve when the fourth period of time has elapsed and the second flow rate of gas of the repeated (b) is initiated.

13. The method of claim 7, wherein the pressure at the inlet junction, while the first flow rate of gas is flowing, the second flow rate of gas is flowing, and third rate of gas is flowing, is controlled while delivering the first flow rate, the second flow rate, and the third flow rate of gas from a gas source through a pressure controller and the inlet junction, wherein controlling the delivery of the first flow rate, the second flow rate, and the third flow rate comprises:
receiving a signal corresponding to a measured pressure from a first pressure-sensing element disposed between the pressure controller and the inlet junction;
receiving a signal corresponding to a measured pressure from a second pressure-sensing element disposed between the first inlet valve and the first backside gas delivery port;
receiving a signal corresponding to a measured pressure from a third pressure-sensing element disposed between the second inlet valve and the second backside gas delivery port of the second processing chamber; and
adjusting the first pressure at the inlet junction based upon the one or more signals.

14. The method of claim 7, wherein the first pressure is between about 2 Torr and about 20 Torr.

15. The method of claim 7, wherein maintaining both the first and second flow rates of gas at the first pressure further comprises maintaining the first pressure within a first pressure tolerance, wherein the first pressure tolerance is between about plus or minus 1 Torr from the first pressure.
venting the gas to a second bypass port that is coupled to the second backside gas delivery port through a second bypass valve.

16. A substrate processing system, comprising:
a first processing chamber comprising:
one or more walls defining a first processing volume;
a first substrate support disposed in the first processing volume, wherein the first substrate support comprises a first backside gas delivery port;
a first backside gas conduit having a first end that is in fluid communication with the first backside gas delivery port and a second end that is in fluid communication with a central junction;
a first inlet valve disposed between the central junction and an inlet junction; and
a first bypass valve disposed between the central junction and a first bypass port, wherein the first bypass port is in fluid communication with the first processing volume;
a second processing chamber comprising:
one or more walls defining a second processing volume;
a second substrate support disposed in the second processing volume, wherein the second substrate support comprises a second backside gas delivery port;
a second backside gas conduit having a first end that is in fluid communication with the second backside gas delivery port and a second end that is in fluid communication with a central junction;
a second inlet valve disposed between the central junction and the inlet junction; and
a second bypass valve disposed between the central junction and a second bypass port, wherein the second bypass port is in fluid communication with the second processing volume;
a pressure controller comprising an inlet and an outlet, wherein the pressure controller is configured to maintain a backside gas at about a configurable backside gas pressure, wherein the outlet of the pressure controller is in fluid communication with the inlet junction;
a flow-regulating orifice comprising an inlet and an outlet, wherein the inlet is coupled to a gas source and the outlet is in fluid communication with the inlet of the pressure controller; and
at least one controller comprising a memory that includes computer-readable instructions stored therein, and the computer-readable instructions, when executed, in real-time, by a processor of the controller, cause:
(a) a delivery of a first flow rate of gas to a first backside gas delivery port coupled to a first substrate support disposed in a first processing volume of a first processing chamber for a first period of time, wherein the delivery of the first flow rate of gas comprises:
delivering the first flow rate of gas to an inlet junction that is coupled to the first backside gas delivery port through a first inlet valve; and
(b) a delivery of a second flow rate of gas to a second backside gas delivery port coupled to a second substrate support disposed in a second processing volume of a second processing chamber for a second period of time, wherein
the second period of time overlaps in time with the first period of time, and the delivery of the second flow rate of gas comprises:
delivering a third flow rate of gas to the inlet junction that is coupled to the second backside gas delivery port through a second inlet valve during the overlap in time of the first and second periods of time, wherein the third flow rate of gas includes the first flow rate of gas and the second flow rate of gas, and
delivering the second flow rate of gas to an inlet junction after the first period of time has elapsed and before the second period of time has elapsed;
wherein a pressure at the inlet junction while the first flow rate of gas is flowing, the second flow rate of gas is flowing, and the third flow rate of gas is flowing, is maintained at a first pressure.

17. The substrate processing system of claim 16, wherein
the pressure at the inlet junction, while the first flow rate of gas is flowing, the second flow rate of gas is flowing, and the third flow rate of gas is flowing, is maintained at the first pressure by delivering the a gas from a gas source through a first orifice and a pressure controller, and
the first orifice and a pressure controller are disposed between the gas source and the inlet junction.

18. The substrate processing system of claim 16, further comprising:
closing the first inlet valve when the first period of time has elapsed; and
opening a first bypass valve for a third period of time when the first period of time has elapsed,
wherein the first bypass valve is coupled between the first backside gas delivery port and a first bypass port, which is in communication with the first processing volume of the first processing chamber.

19. The substrate processing system of claim 18, further comprising:
closing the second inlet valve when the second period of time has elapsed; and
opening a second bypass valve for a fourth period of time when the second period of time has elapsed,
wherein the second bypass valve is coupled between the second backside gas delivery port and a second bypass port, which is in communication with the second processing volume of the second processing chamber.

20. The substrate processing system of claim 19, further comprising:
repeating (a) and (b) at least one more time; and
opening the first inlet valve and closing the first bypass valve when the third period of time has elapsed and the first flow rate of gas of the repeated (a) is initiated.

21. The substrate processing system of claim 20, further comprising:
opening the second inlet valve and closing the second bypass valve when the fourth period of time has elapsed and the second flow rate of gas of the repeated (b) is initiated.
